(19) United States
(12) Patent Application Publication
(10) Pub. No.: US 2006/0220155 A1
(43) Pub. Date: Oct. 5, 2006

(54) SEMICONDUCTOR DEVICE

(75) Inventor: Kenichi FURUTA, Tokyo (JP)

Correspondence Address: GLOBAL IP COUNSELORS, LLP, 1233 20TH STREET, NW, SUITE 700, WASHINGTON, DC, 20036-2680, US

(73) Assignee: OKI ELECTRIC INDUSTRY CO., LTD., Tokyo (JP)

(21) Appl. No.: 11/276,822

(22) Filed: Mar. 15, 2006

(30) Foreign Application Priority Data
Mar. 29, 2005 (JP) 2005/095446

(51) Int. Cl. H01L 29/76

(52) U.S. Cl. 257/409

(57) ABSTRACT

A semiconductor device has a semiconductor substrate, a gate insulator, a gate electrode, and a pair of lightly doped regions. The gate insulator is formed on the semiconductor substrate. The gate electrode is formed on the gate insulator and has first bottom faces and second bottom faces. The distance of the second bottom faces from the surface of the semiconductor substrate is different from that of the first bottom faces, and the first bottom faces and the second bottom faces are disposed alternately along a predetermined direction. The pair of lightly doped regions are formed in regions in the semiconductor substrate except for a region underneath the gate electrode.

### BACKGROUND OF THE INVENTION

1. Field of the Invention

The present invention relates to a semiconductor device which in particular is suitable for being applied to an output transistor in which a comparatively high withstand voltage characteristic is required. Furthermore, the present invention relates to a method of manufacturing such semiconductor device, and an output circuit and an electric device including such semiconductor device.

2. Background Information

Conventionally, in a typical electric device etc., an output circuit for driving electric potentials of output is provided. Normally, this output circuit has a structure which includes transistors disposed in an output stage. In the following, such transistors disposed in the output stage will be referred to as output transistors.

Normally, in the output transistor, a structure having a comparatively high withstand voltage characteristic as compared to a normal transistor which would be built in an internal circuit etc., for instance, is applied to. In the following, such transistor will be referred to as a high voltage transistor. Examples of a structure of a prior art high voltage transistor are disclosed in Japanese Laid-Open Patent Application No. 2003-100771 (hereinafter to be referred to as Patent Reference 1) and Japanese Laid-Open Patent Application No. 2003-204062 (hereinafter to be referred to as Patent Reference 2).

Now, with reference to FIG. 1 and FIG. 2, a structure of a prior art high voltage transistor 900 will be described. FIG. 1 is an overhead view of the high voltage transistor 900. FIG. 2 is a sectional view of the high voltage transistor 900 taken along a line i-i′ shown in FIG. 1.

As shown in FIG. 1 and FIG. 2, the prior art high voltage transistor 900 has a semiconductor substrate 911 in which active regions (also referred to as element forming regions) AR and field regions (also referred to as element isolating regions) FR are defined by element isolating insulation films 912. In the active region AR of the semiconductor substrate 911, a source region 917s and a drain region 917d are formed by having a predetermined impurities diffused therein. On the region sandwiched by the source region 917s and the drain region 917d, a gate insulation film 913 is formed, and on the gate insulation film 913, a gate electrode 915 is formed. Accordingly, the region sandwiched by the source region 917s and the drain region 917d functions as a region where a channel is to be formed (hereinafter, this region will be referred to as a channel forming region 916).

Each of the source region 917s and the drain region 917d has a region which overlaps the gate electrode 915. In this description, such region will be referred to as an overlap region. By having such overlap region, it is possible to turn on and off the output transistor 900 surely, at the time of driving.

On the semiconductor substrate 911 having the structure as described above being built therein, an interlayer insulation film 921 is formed. The interlayer insulation film 921 has contact holes which expose parts of the upper surfaces of the source region 917s and the drain region 917d, respectively. On the interlayer insulation film 921, a source electrode 923s and a drain electrode 923d, which are wiring layers enabling electrical connections with other elements, are formed. The source electrode 923s and the drain electrode 923d are electrically connected with the source region 917s and the drain region 917d via contact plugs 922s and 922d that fill the contact holes, respectively.

However, in the structure as described above, a current flowing between the source and drain will flow intensively into boundary parts a under the edges of the gate electrode 915, i.e. the circled regions shown in FIG. 2. Therefore, if a considerably large amount of current flows between the source and drain by ESD (Electro Static Discharge) for instance, considerably large electric fields will be generated in the boundary parts a. This will lead to problems such as deterioration and damage being easily caused to the boundary parts a.

In this way, the prior art high voltage transistor has a problem in which a withstand voltage characteristic with respect to ESD etc. is insufficient.

In view of the above, it will be apparent to those skilled in the art from this disclosure that there exists a need for an improved semiconductor device, an improved method of manufacturing a semiconductor device, and an improved output circuit and an improved electric device including such improved semiconductor device. This invention addresses this need in the art as well as other needs, which will become apparent to those skilled in the art from this disclosure.

### SUMMARY OF THE INVENTION

It is therefore an object of the present invention to resolve the above-described problems and to provide a semiconductor device having a good withstand voltage characteristic and which is easy to manufacture, a method of manufacturing such semiconductor device, and an output circuit and an electric device including such semiconductor device.

In accordance with a first aspect of the present invention, a semiconductor device has a semiconductor substrate, a gate insulator, a gate electrode, and a pair of lightly doped regions. The gate insulator is formed on the semiconductor substrate. The gate electrode is formed on the gate insulator and has first bottom faces and second bottom faces. The distance of the second bottom faces from the surface of the semiconductor substrate is different from that of the first bottom faces, and the first bottom faces and the second bottom faces are disposed alternately along a predetermined direction. The pair of lightly doped regions are formed in regions except for a region underneath the gate electrode in the semiconductor substrate.

In accordance with a second aspect of the present invention, a method of manufacturing a semiconductor device comprising the steps of preparing a semiconductor substrate; forming a gate insulator on the semiconductor substrate; forming a gate electrode on the gate insulator, the gate electrode having first bottom faces and second bottom faces of which distance from the surface of the semiconductor substrate is different from that of the first bottom faces, the first bottom faces and the second bottom faces being disposed alternately along a predetermined direction; and forming a pair of lightly doped regions in the semiconductor substrate, the pair of lightly doped regions sandwiching a region underneath the gate electrode.

In accordance with a third aspect of the present invention, an output circuit has a transistor designed at an output stage. The transistor has a semiconductor substrate, a gate insulator formed on the semiconductor substrate, a gate electrode formed on the gate insulator, and a pair of lightly doped regions formed in regions except for a region underneath the gate electrode in the semiconductor substrate. The gate electrode has first bottom faces and second bottom faces. The distance of the second bottom faces from the surface of the semiconductor substrate is different from that of the first bottom faces, and the first bottom faces and the second bottom faces are disposed alternately along a predetermined direction.

In accordance with a fourth aspect of the present invention, an electronic device has a transistor designed at an output stage. The transistor has a semiconductor substrate, a gate insulator formed on the semiconductor substrate, a gate electrode formed on the gate insulator, and a pair of lightly doped regions formed in regions except for a region underneath the gate electrode in the semiconductor substrate. The gate electrode has first bottom faces and second bottom faces. The distance of the second bottom faces from the surface of the semiconductor substrate is different from that of the first bottom faces, and the first bottom faces and the second bottom faces are disposed alternately along a predetermined direction, and

These and other objects, features, aspects, and advantages of the present invention will become apparent to those skilled in the art from the following detailed description, which, taken in conjunction with the annexed drawings, discloses preferred embodiments of the present invention.

### BRIEF DESCRIPTION OF THE DRAWINGS

Referring now to the attached drawings which form a part of this original disclosure:

FIG. 1 is an overhead view showing a structure of a prior art high voltage transistor;

FIG. 2 is a sectional view of the prior art high voltage transistor taken along a line i-i′ shown in FIG. 1;

FIG. 3 is an overhead view showing a structure of a semiconductor device according to a first embodiment of the present invention;

FIG. 4 is a sectional view of the semiconductor device according to the first embodiment of the present invention taken along a line I-I′ shown in FIG. 3;

FIG. 5 is a sectional view of the semiconductor device according to the first embodiment of the present invention taken along a line II-II′ shown in FIG. 3;

FIG. 6 is a sectional view of the semiconductor device according to the first embodiment of the present invention taken along a line III-III′ shown in FIG. 3;

FIG. 7 is a sectional view of the semiconductor device according to the first embodiment of the present invention taken along a line IV-IV′ shown in FIG. 3;

FIG. 8A to FIG. 11B are diagrams showing processes of manufacturing the semiconductor device according to the first embodiment of the present invention;

FIG. 12 is a circuit diagram showing an electronic circuit comprising the semiconductor device according to the first embodiment of the present invention;

FIG. 13 is an overhead view showing a structure of a semiconductor device according to a second embodiment of the present invention;

FIG. 14 is a sectional view of the semiconductor device according to the second embodiment of the present invention taken along a line V-V′ shown in FIG. 13;

FIG. 15 is a sectional view of the semiconductor device according to the second embodiment of the present invention taken along a line VI-VI′ shown in FIG. 13;

FIG. 16 is a sectional view of the semiconductor device according to the second embodiment of the present invention taken along a line VII-VII′ shown in FIG. 3;

FIG. 17A to FIG. 19B are diagrams showing processes of manufacturing the semiconductor device according to the second embodiment of the present invention;

FIG. 20 is a sectional view of a semiconductor device 2′ according to the present invention corresponding to the cross section taken along the line II-II′ in FIG. 3; and

FIG. 21 is a sectional view of a semiconductor device 2″ according to the present invention corresponding to the cross section taken along the line II-II′ in FIG. 3.

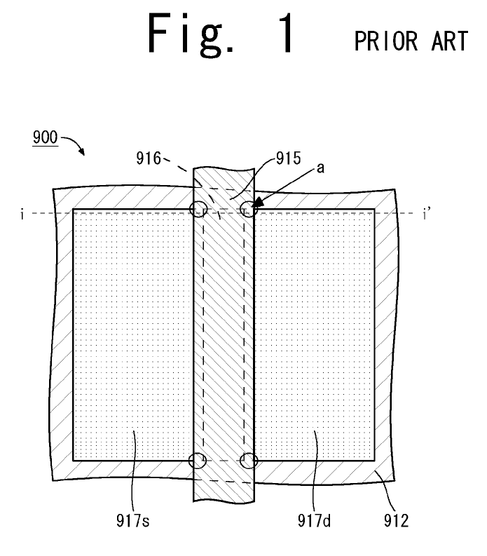

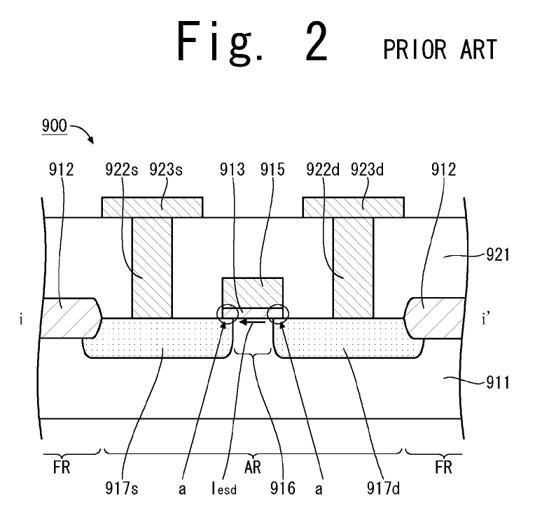

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

### First Embodiment

First, a first embodiment of the present invention will be described in detail with reference to the drawings. This embodiment will show a semiconductor device 1, the structure of which is suitable for being applied to an output transistor in which comparatively high withstand voltage is required, as an example of the present invention.

Structure

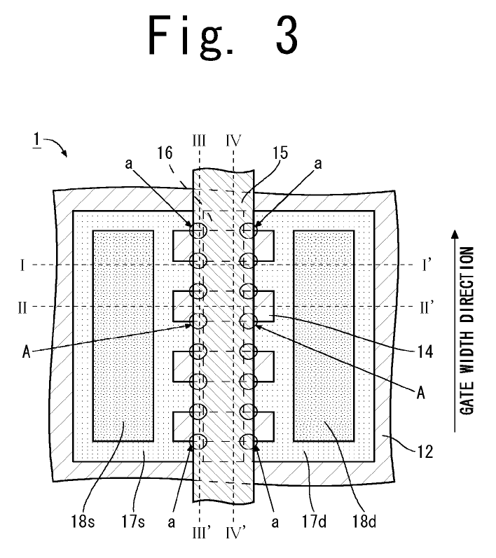

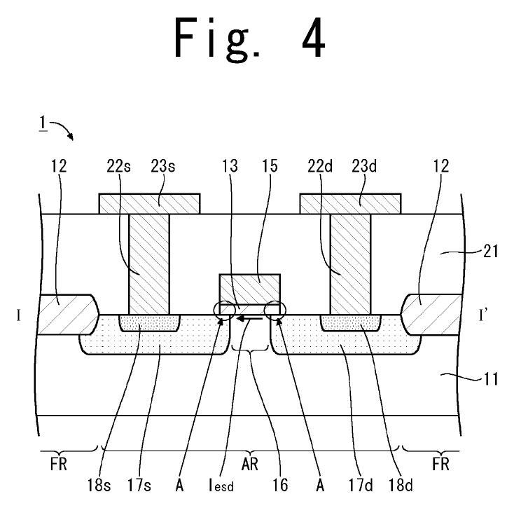

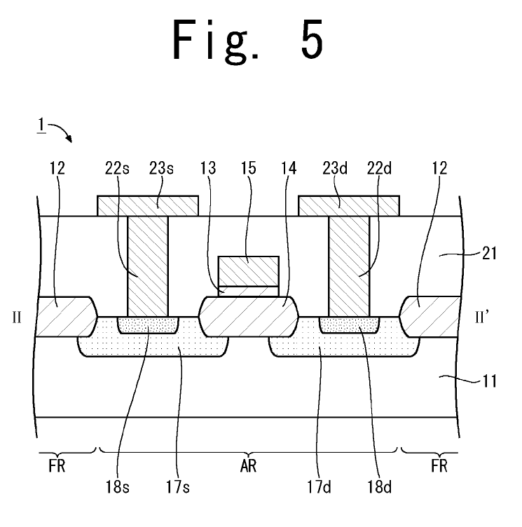

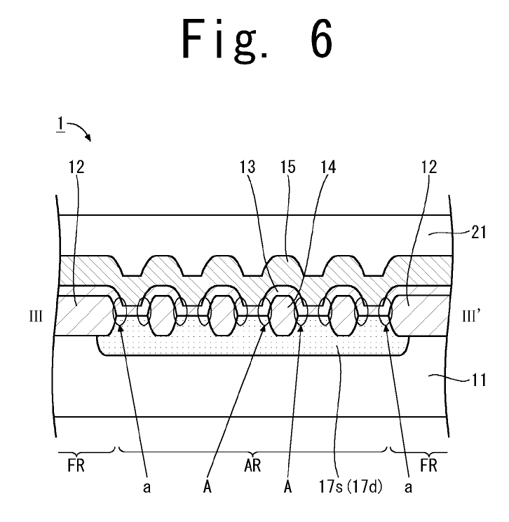

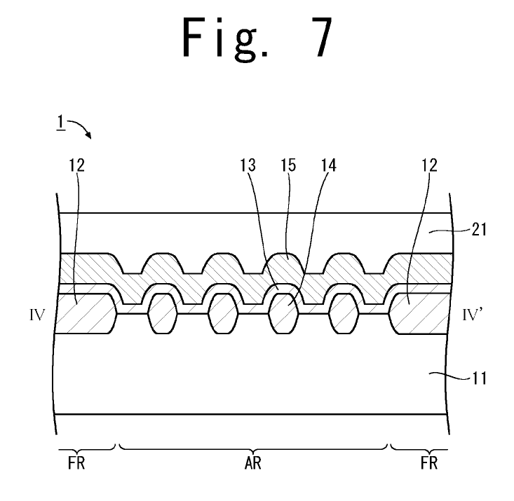

FIG. 3 is an overhead view of a structure of the semiconductor device 1 according to the first embodiment of the present invention. FIG. 4 is a sectional view of the structure of the semiconductor device 1 taken along a line I-I′ shown in FIG. 3, FIG. 5 is a sectional view of the structure of the semiconductor device 1 taken along a line II-II′ shown in FIG. 3, FIG. 6 is a sectional view of the structure of the semiconductor device 1 taken along a line III-IIII′ shown in FIG. 3, and FIG. 7 is a sectional view of the structure of the semiconductor device 1 taken along a line IV-IV′ shown in FIG. 3.

As shown in FIG. 3 to FIG. 7, the semiconductor device 1 has a semiconductor substrate 11, field oxides 12 (which are also called element isolating insulation films) formed in the semiconductor substrate 11, a gate insulator 13 formed on the semiconductor substrate 11, a gate electrode 15 formed on the gate insulator 13, lightly doped regions 17s and 17d sandwiching a region underneath the gate electrode 15 in the semiconductor substrate 11, and highly doped regions 18s and 18d formed on the surfaces of the lightly doped regions 17s and 17d, respectively. The region in the semiconductor substrate 11 underneath the gate electrode 15 sandwiched by the lightly doped regions 17s and 17d functions as a region where a channel is to be formed (i.e. a channel forming region 16). The semiconductor device 1 has one or more insulation films 14 formed in the semiconductor substrate 11.

On the semiconductor substrate 11 having the above-described structure being built therein, an interlayer insulation film 21 including contact holes which expose parts of the surfaces of the highly doped regions 18s and 18d, respectively, is formed. The contact holes are filled up with contact plugs 22s and 22d. On the interlayer insulation film 21, a source electrode 23s and a drain electrode 23d are formed. In FIG. 3, in order to clearly show the structure of the semiconductor device 1, structures of the interlayer insulation film 21, the contact plugs 22s and 22d, the source electrode 23s and the drain electrode 23d will be omitted.

In the above-described structure, the semiconductor substrate 11 is a silicon substrate to which n type impurities are doped (hereinafter such silicon substrate will be referred to as an n type silicon substrate), for instance. However, the semiconductor substrate 11 does not necessarily have to be an n type silicon substrate, but can be changed as needed. For instance, it may be a silicon substrate to which p type impurities are doped (hereinafter such silicon substrate will be referred to as a p type silicon substrate).

The field oxide 12 is a film formed using a LOCOS (local oxidation of silicon) method, i.e. a LOCOS film, for instance. Here, this LOCOS film may be a silicon oxide (SiO₂) film, for instance. However, the field oxide 12 does not necessarily have to be a LOCOS film, but may be an insulation film formed by other methods such as an STI (shallow trench isolation) method, for instance. The field oxides 12 define the active regions AR and the field regions FR in the semiconductor substrate 11.

As shown in FIG. 3 to FIG. 7, the gate insulator 13 is formed on a region which divides the active region AR in the semiconductor substrate 11 in two, and it lets the gate electrode 15 electrically float with respect to the semiconductor substrate 11. Here, the gate insulator 13 is a silicon oxide (SiO₂) film formed on the active region AR by conducting thermal oxidation on the surface of the semiconductor substrate 11 for instance, and it may be 100 Å (angstrom) thick for instance.

The gate electrode 15 formed on the gate insulator 13 is a poly-silicon film including predetermined impurities for instance, and it may be 5000 Å thick for instance.

As mentioned above and as shown in FIG. 3 to FIG. 7, the lightly doped regions 17s and 17d are impurity diffused regions sandwiching the region underneath the gate electrode 15 in the semiconductor substrate 11. The lightly doped regions 17s and 17d function as a source (17s) and a source (17s), respectively. For example, if a semiconductor element in the semiconductor device 1 is a transistor which forms a p type channel, the lightly doped regions 17s and 17d can be formed by implanting p type impurities such as boron (B) ions. In this case, a dose amount of the p type impurities may be around 1×10¹²˜1×10¹³/cm² for example. On the other hand, if a semiconductor element in the semiconductor device 1 is a transistor which forms an n type channel, the lightly doped regions 17s and 17d can be formed by implanting n type impurities such as phosphorous (P) ions. In this case, a dose amount of the n type impurities may be around 1×10¹²˜1×10¹³/cm² for example.

As shown in FIG. 3 to FIG. 7, the lightly doped regions 17s and 17d functioning as the source and drain regions, respectively, have regions that overlap the gate electrode 15. That is, the lightly doped regions 17s and 17d have overlap regions, respectively. By having such overlap regions, the semiconductor device can be turned on and off surely at the time of driving.

As can be seen in FIG. 3 to FIG. 7, the region sandwiched by the lightly doped regions 17s and 17d, i.e., the region underneath the gate electrode 15 in the active region AR, functions as the channel forming region 16, as mentioned above. Here, in case when the semiconductor substrate 11 has a well structure for instance, this region should have predetermined impurities doped therein.

As shown in FIG. 3 to FIG. 5, the highly doped regions 18s and 18d are formed in parts of the upper parts of the lightly doped regions 17s and 17d, and they are conductive regions for enabling ohmic contacts with the contact plugs 22s and 22d (which will be described later on), respectively. For example, if a semiconductor element in the semiconductor device 1 is a transistor which forms a p type channel, the highly doped regions 18s and 18d can be formed by implanting p type impurities such as boron (B) ions. In this case, a dose amount of the p type impurities may be around 1×10¹⁵/cm² for example. On the other hand, if a semiconductor element in the semiconductor device 1 is a transistor which forms an n type channel, the highly doped regions 17s and 17d can be formed by implanting n type impurities such as phosphorous (P) ions. In this case, a dose amount of the n type impurities may be around 1×10¹⁵/cm² for example.

As shown in FIG. 3 and FIG. 7, the semiconductor device 1 of this embodiment has one or more insulation films 14 formed in the semiconductor substrate 11. The insulation films 14 are disposed in the active regions underneath the gate electrodes 15 at predetermined intervals along a channel width direction (q.v. FIG. 3, FIG. 6 and FIG. 7). These insulation films 14 are the structure for distancing the gate electrodes 15 from the semiconductor substrate 11 partially. That is, since the gate insulator 13 and the gate electrode 15 are formed over the insulation films 14, in the region where the insulation films 14 are formed, the gate electrode 15 is distanced from the semiconductor substrate 11 by a difference in level between the upper surface of the semiconductor substrate 11 and the upper surface of the insulation film 14. By this arrangement, the gate electrode 15 can be formed to have a structure in which first bottom faces and second bottom faces, in which the height from the upper face of the semiconductor substrate 11 differs from the height of the first bottom faces from the semiconductor substrate 11, are disposed alternately along the gate width direction.

In this way, by forming the gate electrode 15 to have parts that are close to the semiconductor substrate 11 and parts that are far from the semiconductor substrate 11, especially with respect to the lightly doped regions 17s and 17d in the overlap regions of the semiconductor substrate 11, it is possible to form current paths in between the source and drain, in boundary regions A, which are shown as circled in FIG. 3, FIG. 4 and FIG. 6, in addition to boundary regions a (q.v. FIG. 3 and FIG. 6) between the active region AR and the adjacent field regions FR under the gate electrode 15. Here the boundary region A is a part where the close part with respect to the semiconductor substrate 11 switches to the far part with respect to the semiconductor substrate 11. Accordingly, in this structure, it is possible to increase the number of current paths as compared to the conventional cases.

Furthermore, as shown in FIG. 3, FIG. 6 and FIG. 7, by disposing the insulation films 14 along the channel width direction at predetermined intervals, it is possible to simplify the shape of a photo-mask for forming the insulation films 14. In addition to that, it is possible to increase the number of current paths according to the channel width. As a result, it is possible to provide the semiconductor device 1 with a withstand voltage characteristic which depends on the channel width. In other words, it is possible to provide the semiconductor device 1 with a withstand voltage characteristic having a W dependency property. Here, ‘W’ indicates the channel width.

In this embodiment, the insulation film 14 is a film formed by the LOCOS method (i.e. a LOCOS film). Here, this LOCOS film may be a silicon oxide film. Therefore, the insulation films 14 can be formed by the same processes as the ones for forming the field oxides 12, and it is possible to make the structures in the boundary regions a and the structures in the boundary regions A the same (q.v. FIG. 3 and FIG. 6). By making the structures in the boundary regions a and in the boundary regions A the same, it is possible to pass an electric current to the boundary regions a and the boundary regions A evenly, which results in improving the withstand voltage characteristic.

On the semiconductor substrate 11 having the above-described structure being built therein, the interlayer insulation film 21 is formed. The interlayer insulation film 21 includes contact holes which expose parts of the upper surfaces of the highly doped regions 18s and 18d, respectively. On the interlayer insulation film 21, the source electrode 23s and the drain electrode 23d, which are wiring layers enabling electrical connections with other elements, are formed. The source electrode 23s and the drain electrode 23d are electrically connected with the highly doped regions 18s and 18d, respectively, through the contact plugs 22s and 22d filling up the contact holes, respectively.

Manufacturing Method

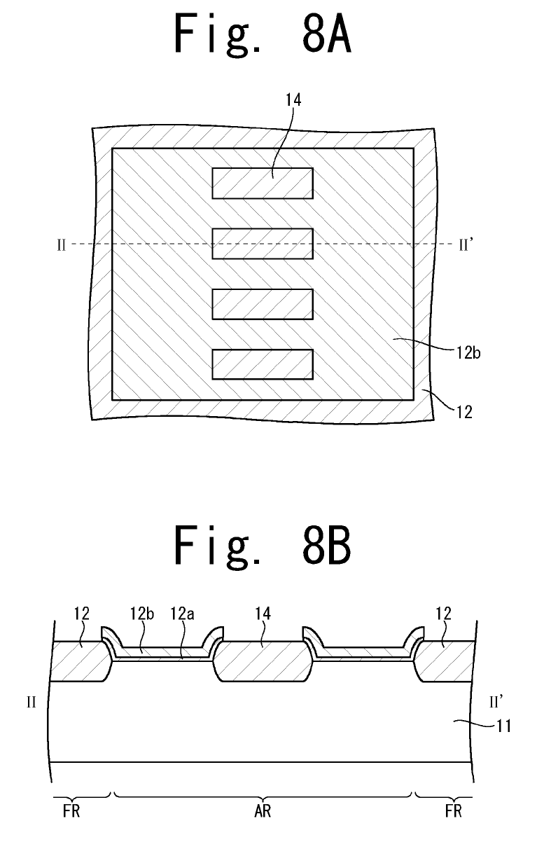

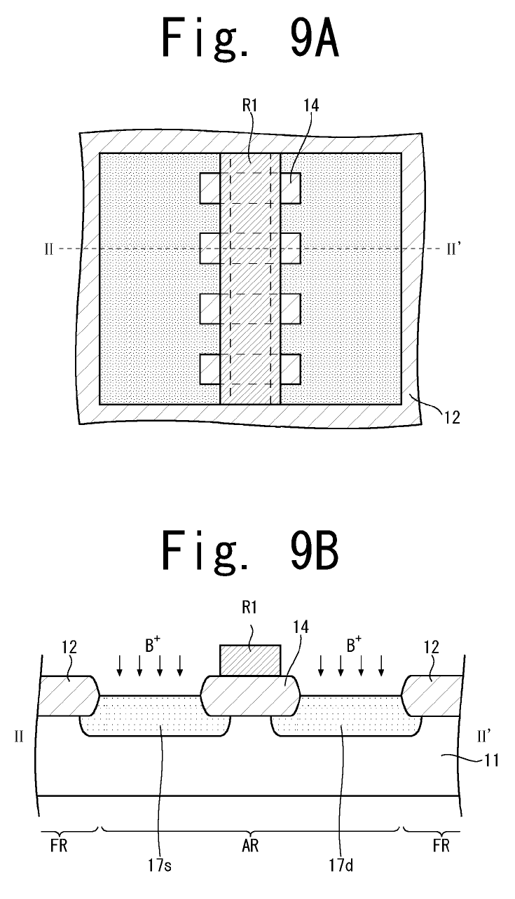

Now, a method of manufacturing the semiconductor device 1 according to the first embodiment of the present invention will be described in detail with reference to the drawings. FIG. 8A to FIG. 11B are diagrams showing processes of manufacturing the semiconductor device 1 according to the first embodiment of the present invention. Among these drawings, FIG. 8A and FIG. 9A show overhead views of the semiconductor substrate 11, and FIG. 8B, FIG. 9B and FIG. 10A to FIG. 11B show sectional views of the semiconductor substrate 11 corresponding to the cross section taken along the line II-II′ in FIG. 3.

In this manufacturing method, first, a semiconductor substrate 11 is prepared. Next, by conducting a thermal oxidation treatment on the surface of the semiconductor substrate 11, a silicon oxide film which is a buffer film is formed on the entire surface of the semiconductor substrate 11. Then, by depositing silicon nitride on the silicon oxide film, a silicon nitride film is formed on the silicon oxide film.

Next, using a known photolithographic process and an etching process, the silicon nitride film and the silicon oxide film are processed into silicon nitride films 12b and silicon oxide films 12a. In this process, a photo-mask used in the photolithographic process has a pattern including upper shapes of the field regions (i.e. the field oxides 12) and the insulation films 14. After forming the silicon nitride films 12b and the silicon oxide films 12a, by conducting a thermal oxidation treatment on the surface of the semiconductor substrate 11 while using the processed silicon nitride films 12b as masks, the field oxides 12 and the insulation films 14 which are LOCOS films are formed simultaneously on the exposed semiconductor substrate 11, as shown in FIG. 8A and FIG. 8B. As for the conditions of the thermal oxidation treatment, for instance, an environment inside oven is set to oxygen and hydrogen environment, the heating temperature is set to around 1000° C., and the heating time is set to around 100 minutes. By this arrangement, the field oxides 12 and the insulation films 14 each of which has a thickness of about 5000 Å can be formed. After forming the field oxides 12 and the insulation films 14, the silicon nitride films 12b are removed by etching under predetermined conditions.

Next, by conducting a known photolithographic process, a photoresist R1 is formed over a region corresponding to a region underneath a gate electrode 15 which is to be formed in a post process. Then, predetermined impurities are implanted into the active regions AR in the semiconductor substrate 11 while using the photoresist R1 and the field oxides 12 as masks. Then, by conducting thermal diffusion on the semiconductor substrate 11 for diffusing the implanted impurities, lightly doped regions 17s and 17d are formed in the active regions AR of the semiconductor substrate 11, as shown in FIG. 9A and FIG. 9B. Here, as for the conditions of implanting the predetermined impurities in case where the semiconductor device 1 of this embodiment has a p-type transistor, for instance, boron (B) ions are used as the predetermined impurities, the accelerating energy thereof is set to around 500 KeV (kilo electron volt), and the dose amount thereof is set to around 1×10¹² to 1×10¹³/cm². Furthermore, in this case, as for the condition of the thermal diffusion, the heating temperature is set to 1000° C., for instance. On the other hand, as for the conditions of implanting the predetermined impurities in case where the semiconductor device 1 of this embodiment has an n-type transistor, for instance, phosphorus (P) ions are used as the predetermined impurities, the accelerating energy thereof is set to around 500 KeV, and the dose amount thereof is set to around 1×10¹² to 1×10¹³/cm². Furthermore, in this case, as for the condition of the thermal diffusion, the heating temperature is set to around 1000° C., for instance. After forming the lightly doped regions 17s and 17d, the photoresist R1 is removed.

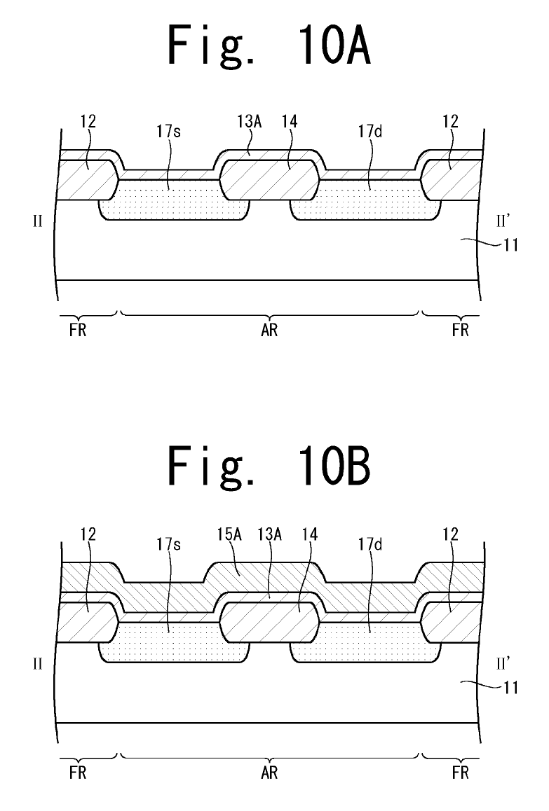

Next, by conducting a thermal oxidation treatment on the surface of the semiconductor substrate 11 where the lightly doped regions 17s and 17d are formed, a silicon oxide film 13A having a thickness of about 100 Å, for instance, is formed on the semiconductor substrate 11 and the insulation films 14, as shown in FIG. 10A. As for the conditions of the thermal oxidation treatment, for instance, the environment inside an oven is set to an oxygen and hydrogen environment, the heating temperature is set to around 850° C., and the heating time is set to around 20 minutes.

Next, by depositing silicon including predetermined impurities on the silicon oxide film 13A using a CVD method or a sputtering method for instance, a polysilicon film 15A having a thickness of about 5000 Å and including the predetermined impurities is formed on the silicon oxide film 13A. Accordingly, the structure as shown in FIG. 10B can be obtained.

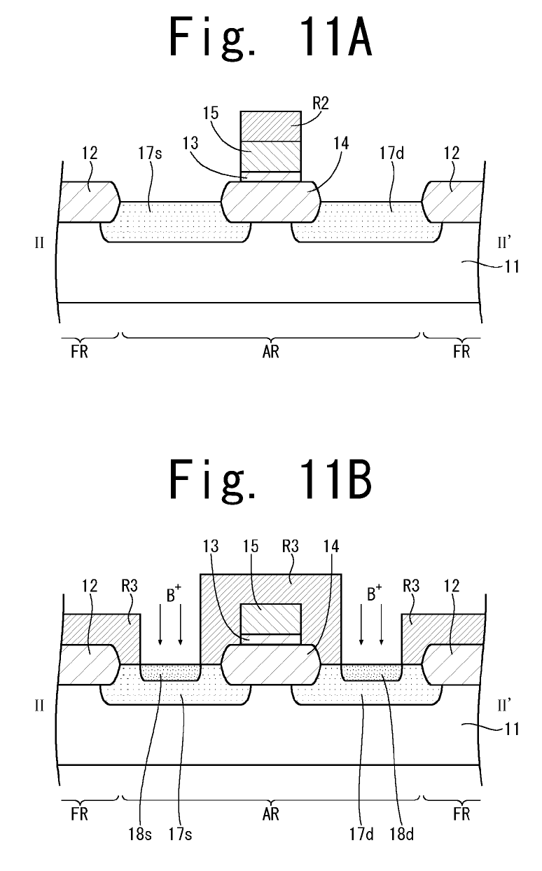

Next, by conducting a known photolithographic process, a photoresist R2 having a pattern including the upper shape of the gate electrode 15 is formed on the polysilicon film 15A. Then, by etching the polysilicon film 15A and the silicon oxide film 13A sequentially while using the photoresist R2 as a mask, the gate electrode 15 and the gate insulator 13 are formed over the semiconductor substrate 11 and the insulation film 14, as shown in FIG. 11A. As for the etching of the polysilicon film 15A and the silicon oxide film 13A, it is possible to use a dry etching method or a wet etching method. If a dry etching method is used in etching the polysilicon film 15A for instance, with respect to the conditions of this dry etching process for instance, it is possible to use a mixed gas of Cl₂, HBr₃ and O₂ as an etching gas. In this case, the flow ratio of the mixed gas is set to about Cl₂:HBr₃:O₂=100:100:2˜4, for instance. If a dry etching method is used in etching the silicon oxide film 13A for instance, with respect to the conditions of this dry etching process for instance, it is possible to use a mixed gas of CF₄ and CHF₃ as an etching gas. In this case, the flow ratio of the mixed gas is set to about CF₄:CHF₃=1:10, for instance.

Next, by conducting a known photolithographic process, a photoresist R3 having openings which expose parts of the surface of the lightly doped regions 17s and 17d is formed over the semiconductor substrate 11. Then, by having predetermined impurities implanted into the lightly doped regions 17s and 17d while using the photoresist R3 as a mask, highly doped regions 18s and 18d are formed in the upper parts of the lightly doped regions 17s and 17d, as shown in FIG. 11B. Here, as for the conditions of implanting the predetermined impurities in case where the semiconductor device 1 of this embodiment has a p-type transistor, for instance, boron (B) ions are used as the predetermined impurities, the accelerating energy thereof is set to around 50 KeV, and the dose amount thereof is set to around 1×10¹⁵/cm². On the other hand, as for the conditions of implanting the predetermined impurities in case where the semiconductor device 1 of this embodiment has an n-type transistor, for instance, phosphorus (P) ions are used as the predetermined impurities, the accelerating energy thereof is set to around 50 KeV, and the dose amount thereof is set to around 1×10¹⁵/cm². After forming the highly doped regions 18s and 18d, the photoresist R3 is removed.

Next, by depositing silicon oxide over the semiconductor substrate 11 on which the structure described above is formed, an interlayer insulation film 21 burying the structure is formed over the semiconductor substrate 11. Then, contact holes exposing the upper surfaces of the highly doped regions 18s and 18d are formed in the interlayer insulation film 21 using a known photolithographic process and a known etching process, and contact plugs 22s and 22d are formed by filling in tungsten (W) inside the contact holes. Then, by forming a conductive film on the interlayer insulation film 21 and processing this conductive film using a known photolithographic process and a known etching process, a source electrode 23s and a drain electrode 23d electrically connecting with the contact plugs 22s and 22d, respectively, are formed on the interlayer insulation film 21.

Taking the processes described above, the semiconductor device 1 having the structure represented by the cross section shown in FIG. 3 to FIG. 7 can be produced.

As described above, the semiconductor device 1 according to the first embodiment of the present invention has a semiconductor substrate 11, a gate insulator 13 formed on the semiconductor substrate 11, a gate electrode 15 which is formed on the gate insulator 13 and has a structure in which first bottom faces and second bottom faces, of which the distance from the surface of the semiconductor substrate 11 is different from the first bottom faces, are disposed alternately along the gate width direction, and lightly doped regions 17s and 17d formed in regions except for a region underneath the gate electrode 15 in the semiconductor substrate 11.

In this way, by forming the gate electrode 15 as having parts that are close to the semiconductor substrate 11 (e.g. the first bottom faces) and parts that are far from the semiconductor substrate 11 (e.g. the second bottom faces), it is possible to form paths for the current flowing in between the source and drain, in boundary regions A, in addition to boundary regions a between the active region AR and the adjacent field regions FR under the gate electrode 15. Here, the boundary region A is a part where the close part with respect to the semiconductor substrate 11 switches to the far part with respect to the semiconductor substrate 11. Accordingly, in this structure, it is possible to increase the number of current paths as compared to the conventional cases. As a result, it is possible to realize a semiconductor device 1 having a good withstand voltage characteristic.

Furthermore, according to this embodiment, it is possible to form the insulation films together with the field oxides, for instance, using the LOCOS method. Accordingly, a typical manufacturing method of a semiconductor device can be applied with a partial change in a photo-mask in a process of forming the element formation regions, and it is not necessary to increase the number of processes in the manufacturing method. Therefore, the semiconductor device 1 of this embodiment can be manufactured easily at low cost.

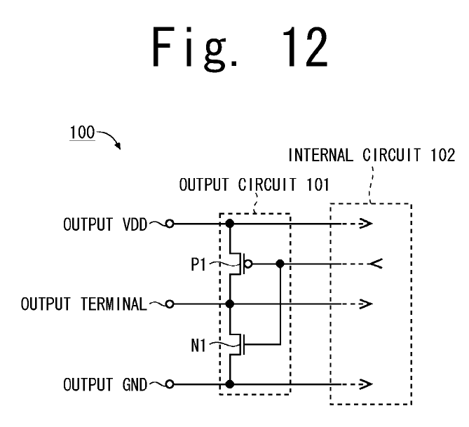

FIG. 12 shows a circuit diagram of an electronic circuit 100 comprising the semiconductor device 1 according to this embodiment. As shown in FIG. 12, the electronic circuit 100 has an output circuit 101 and an internal circuit 102. The output circuit 101 has a p-type output transistor P1 and an n-type output transistor N1. The p-type output transistor P1 is connected between an output terminal and a terminal (output VDD) which is connected to an output power supply voltage. The n-type output transistor N1 is connected between the output terminal and a terminal (output GND) which is connected to the ground. The p-type output transistor P1 and the n-type output transistor N1 are formed on a predetermined semiconductor substrate (i.e. the semiconductor substrate 11) using the structure according to this embodiment.

By having such structure, an output circuit with an improved withstanding characteristic with respect to ESD (Electro Static Discharge) and an electronic device having such output circuit can be provided.

### Second Embodiment

Next, a second embodiment of the present invention will be described in detail with reference to the drawings. In the following, as for the structure that are the same as the first embodiment, the same reference number will be used, and redundant explanations of those structure elements will be omitted.

Structure

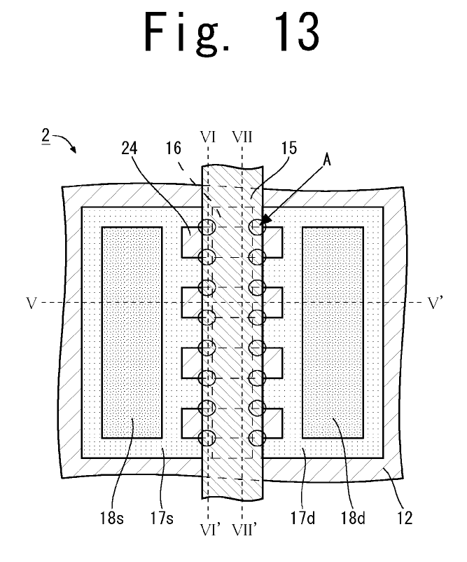

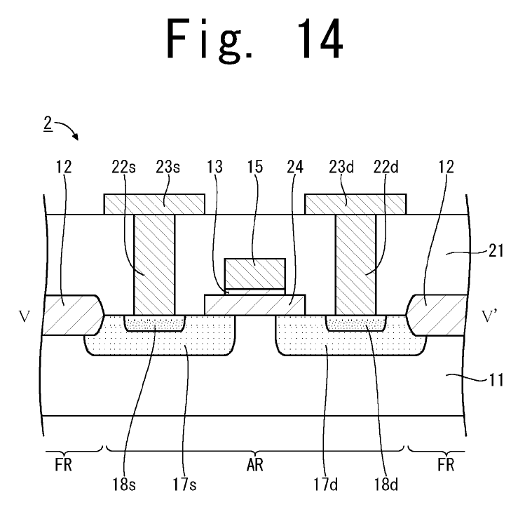

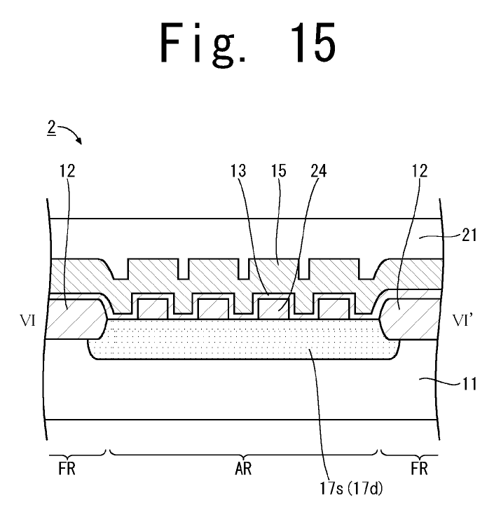

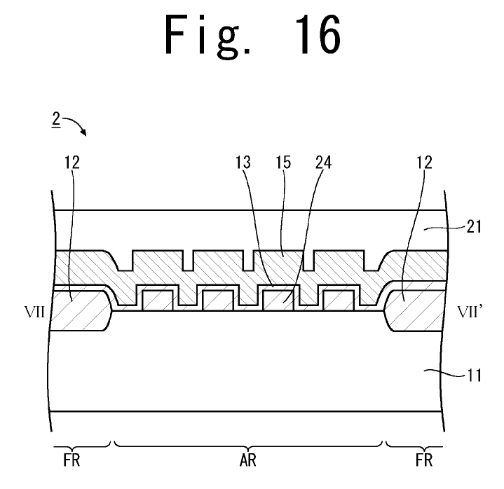

FIG. 13 is an overhead view of a structure of the semiconductor device 2 according to the second embodiment of the present invention. FIG. 14 is a sectional view of the structure of the semiconductor device 2 taken along a line V-V′ shown in FIG. 13, FIG. 15 is a sectional view of the structure of the semiconductor device 2 taken along a line VI-VI′ shown in FIG. 13, and FIG. 16 is a sectional view of the structure of the semiconductor device 2 taken along a line VII-VII′ shown in FIG. 13. In addition, the cross section structure of the semiconductor device 2 corresponding to the line I-I′ shown in FIG. 13 is the same as the cross section structure shown in FIG. 4, and in this embodiment, FIG. 4 will be referred to in order to explain the cross section structure of the semiconductor device 2.

As shown in FIG. 13 to FIG. 16 and FIG. 4, the semiconductor device 2 has the same structure as the semiconductor device 1 of the first embodiment, except that the insulation films 14 are replaced with insulation films 24.

The insulation film 24 can be a silicon oxide film formed by a CVD method, for instance. However, the insulation film 24 is not limited to the silicon oxide film, and it is appropriate as long as it is an insulation film such as a silicon film, which does not have an adverse influence on other structures.

As described above and shown in FIG. 13, FIG. 15 and FIG. 16, by disposing the insulation films 24 along the channel width direction at predetermined intervals, as with the first embodiment, it is possible to distance the gate electrode 15 from the semiconductor substrate 11 partially. That is, since the gate insulator 13 and the gate electrode 15 are formed over the insulation films 24, in the region where the insulation films 24 are formed, the gate electrode 15 is distanced from the semiconductor substrate 11 by the difference in level between the upper surface of the semiconductor substrate 11 and the upper surface of the insulation films 24. By this arrangement, as with the first embodiment, the gate electrode 15 can be formed as having a structure in which first bottom faces and second bottom faces, in which the height from the upper face of the semiconductor substrate 11 differ from the height of the first bottom faces from the semiconductor 11, are disposed alternately along the gate width direction. Thereby, it is possible to form current paths in between the source and drain, in boundary regions A, which are shown as circled in FIG. 13, FIG. 15 and FIG. 4, in addition to boundary regions a (q.v. FIG. 3 and FIG. 6) between the active region AR and the adjacent field regions FR under the gate electrode 15. Here the boundary region A is a part where the close part with respect to the semiconductor substrate 11 switches to the far part with respect to the semiconductor substrate 11. Accordingly, in this structure, it is possible to increase the number of current paths as compared to the conventional cases.

Furthermore, as described above and shown in FIG. 13, FIG. 15 and FIG. 16, by disposing the insulation films 24 along the channel width direction at predetermined intervals, it is possible to increase the number of current paths according to the channel width. As a result, it is possible to provide the semiconductor device 2 with a withstand voltage characteristic which depends on the channel width. In other words, it is possible to provide the semiconductor device 2 with a withstand voltage characteristic having a W dependency property.

Since the rest of the structure is the same as the structure of the semiconductor device 1 of the first embodiment, detailed description thereof will be omitted.

Manufacturing Method

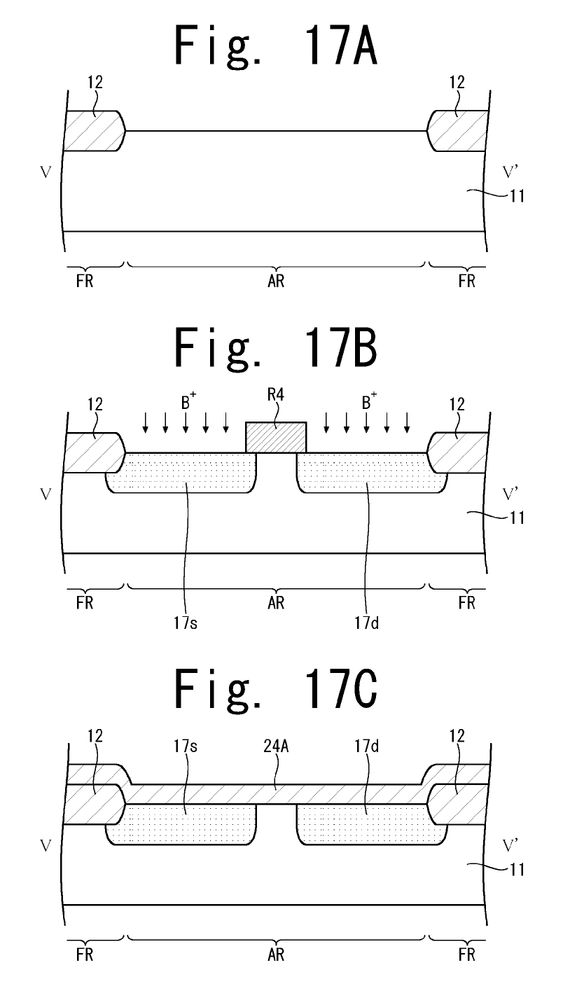

Now, a method of manufacturing the semiconductor device 2 according to the second embodiment of the present invention will be described in detail with reference to the drawings. FIG. 17A to FIG. 19B are diagrams showing processes of manufacturing the semiconductor device 2 according to the second embodiment of the present invention. Here, FIG. 17A to FIG. 19B show sectional views of the semiconductor substrate 11 corresponding to the cross section taken along the line V-V′ in FIG. 13.

In this manufacturing method, first, a semiconductor substrate 11 is prepared. Next, as shown in FIG. 17A, field oxides 12 are formed on the semiconductor substrate 11 using a known LOCOS method. As for the conditions of a thermal oxidation treatment for forming the field oxides 12, for instance, an environment inside oven is set to oxygen and hydrogen environment, the heating temperature is set to around 1000 Å, and the heating time is set to around 100 minutes. By this arrangement, the field oxides 12 having a thickness of about 5000 Å can be formed.

Next, by conducting a known photolithographic process, a photoresist R4 is formed over a region corresponding with a region underneath a gate electrode 15 which is to be formed in a post process. Then, predetermined impurities are implanted into the active regions AR in the semiconductor substrate 11 while using the photoresist R4 and the field oxides 12 as masks. Then, by conducting a thermal diffusion on the semiconductor substrate 11 for diffusing the implanted impurities, as shown in FIG. 17B, lightly doped regions 17s and 17d are formed in the active regions AR of the semiconductor substrate 11. Here, as for the conditions of implanting the predetermined impurities in case where the semiconductor device 2 of this embodiment has a p-type transistor, for instance, boron (B) ions are used as the predetermined impurities, the accelerating energy thereof is set to around 500 KeV, and the dose amount thereof is set to around 1×10¹² to 1×10¹³/cm². Furthermore, in this case, as for the condition of the thermal diffusion, the heating temperature is set to 1000° C., for instance. On the other hand, as for the conditions of implanting the predetermined impurities in case where the semiconductor device 2 of this embodiment has an n-type transistor, for instance, phosphorus (P) ions are used as the predetermined impurities, the accelerating energy thereof is set to around 500 KeV, and the dose amount is set to around 1×10¹² to 1×10¹³/cm². Furthermore, in this case, as for the condition of the thermal diffusion, the heating temperature is set to around 1000° C., for instance. After forming the lightly doped regions 17s and 17d, the photoresist R4 is removed.

Next, by depositing silicon oxide over the surface of the semiconductor substrate 11 where the lightly doped regions 17s and 17d are formed, as shown in FIG. 17C, a silicon oxide film 24A is formed on the semiconductor substrate 11 and the field oxides 12. This silicon oxide film 24A is a CVD film and it is to be processed into insulation films 24 in a post process. The thickness of the silicon oxide film 24A can be the same thickness as the field oxides 12, e.g. about 5000 Å. In this way, by conforming the thicknesses of the field oxides 12 and the insulation films 24, it is possible to conform the structure in the boundary regions A (q.v. FIG. 13 and FIG. 15) and the structure in the boundary regions a (q.v. FIG. 13 and FIG. 15). Therefore, it is possible to make the current flowing through the boundary regions A equal to the current flowing through the boundary regions a when a comparatively large current such as a static electrical charge or the like flows in between the source and drain. That is, it is possible to conform the characteristics of each of the boundary regions A and a. As a result, the withstand voltage characteristic of the semiconductor device 2 can be improved.

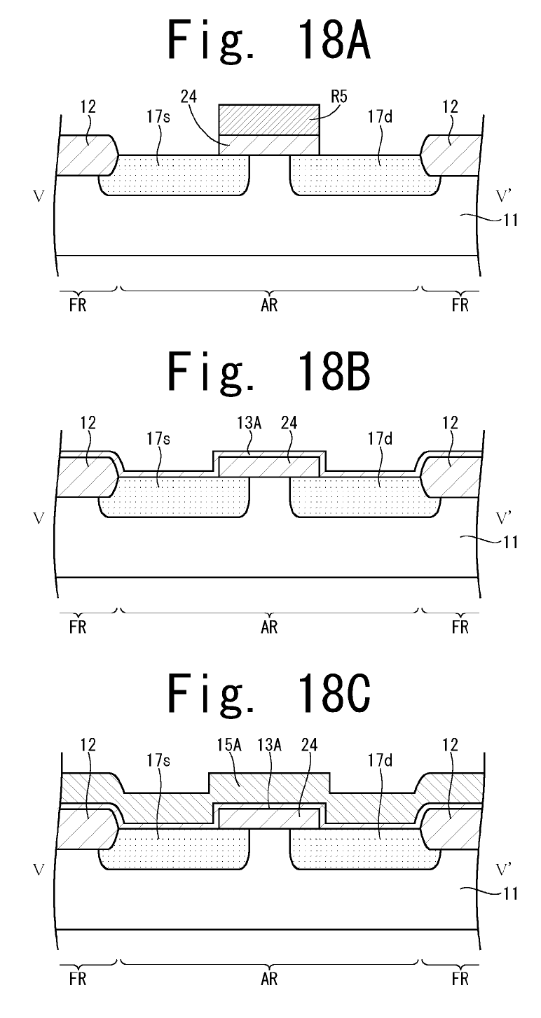

Next, by conducting a known photolithographic process, a photoresist R5 having a pattern including the upper shapes of the insulation films 24 is formed on the silicon oxide film 24A. Then, by etching the silicon oxide film 24A while using the photoresist R5 as a mask, insulation films 24 are formed on the semiconductor substrate 11, as shown in FIG. 18. As for the etching of the silicon oxide film 24A, it is possible to use a dry etching method or a wet etching method. If a dry etching method is used in etching the silicon oxide film 24A for instance, with respect to the conditions of this dry etching process for instance, it is possible to use a mixed gas of CF₄ and CHF₃ as an etching gas. In this case, the flow ratio of the mixed gas is set to about CF₄:CHF₃=1:10, for instance. In addition, the insulation films 24 formed by etching the silicon oxide film 24A are CVD films, like the silicon oxide film 24A itself. After forming the insulation films 24, the photoresist R5 is removed.

Next, by conducting a thermal oxidation treatment on the surface of the semiconductor substrate 11, a silicon oxide film 13A having a thickness of about 100 Å, for instance, is formed on the semiconductor substrate 11 and the insulation films 24, as shown in FIG. 18B. As for the conditions of the thermal oxidation treatment, for instance, the environment inside the oven is set to an oxygen and hydrogen environment, the heating temperature is set to around 850° C., and the heating time is set to around 20 minutes.

Next, by depositing silicon including predetermined impurities on the silicon oxide film 13A using a CVD method or a sputtering method for instance, a polysilicon film 15A having a thickness of about 5000 Å and including the predetermined impurities is formed on the silicon oxide film 13A. Accordingly, the structure as shown in FIG. 18C can be obtained.

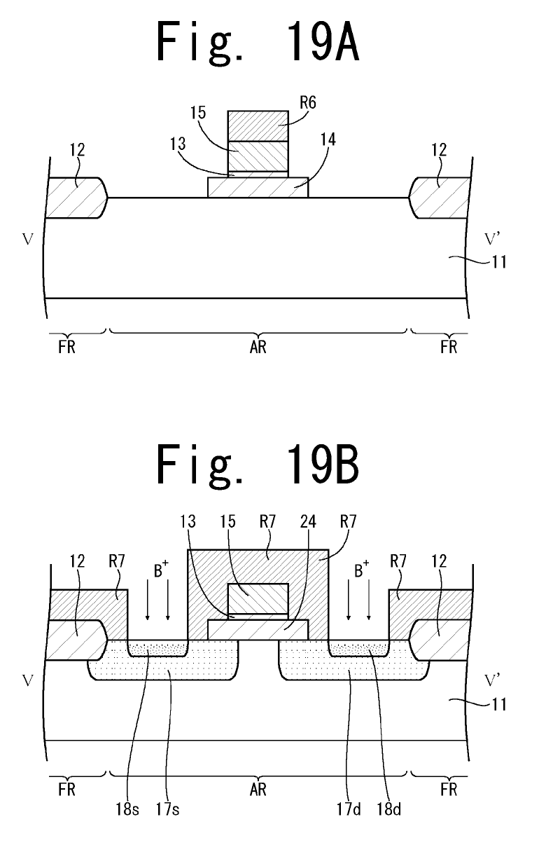

Next, by conducting a known photolithographic process, a photoresist R6 having a pattern including the upper shape of the gate electrode 15 is formed on the polysilicon film 15A. Then, by etching the polysilicon film 15A and the silicon oxide film 13A sequentially while using the photoresist R6 as a mask, the gate electrode 15 and the gate insulator 13 are formed on over the semiconductor substrate 11 and the insulation films 24, as shown in FIG. 19A. As for the etching of the polysilicon film 15A and the silicon oxide film 13A, it is possible to use a dry etching method or a wet etching method. If a dry etching method is used in etching the polysilicon film 15A for instance, with respect to the conditions of this dry etching process for instance, it is possible to use a mixed gas of Cl₂, HBr₃ and O₂ as an etching gas. In this case, the flow ratio of the mixed gas is set to about Cl₂:HBr₃:O₂=100:100:2˜4, for instance. If a dry etching method is used in etching the silicon oxide film 13A for instance, with respect to the conditions of this dry etching process for instance, it is possible to use a mixed gas of CF₄ and CHF₃ as an etching gas. In this case, the flow ratio of the mixed gas is set to about CF₄:CHF₃=1:10, for instance.

Next, by conducting a known photolithographic process, a photoresist R7 having openings which expose parts of the surface of the lightly doped regions 17s and 17d is formed over the semiconductor substrate 11. Then, by having predetermined impurities implanted into the lightly doped regions 17s and 17d while using the photoresist R7 as a mask, highly doped regions 18s and 18d are formed in the upper parts of the lightly doped regions 17s and 17d, as shown in FIG. 19B. Here, as for the conditions of implanting the predetermined impurities in case where the semiconductor device 2 of this embodiment has a p-type transistor, for instance, boron (B) ions are used as the predetermined impurities, the accelerating energy thereof is set to around 50 KeV, and the dose amount thereof is set to around 1×10¹⁵/cm². On the other hand, as for the conditions of implanting the predetermined impurities in case where the semiconductor device 2 of this embodiment has an n-type transistor, for instance, phosphorus (P) ions are used as the predetermined impurities, the accelerating energy thereof is set to around 50 KeV, and the dose amount thereof is set to around 1×10¹⁵/cm². After forming the highly doped regions 18s and 18d, the photoresist R7 is removed.

Next, by depositing silicon oxide over the semiconductor substrate 11 on which the structure described above is formed, an interlayer insulation film 21 burying the structure is formed over the semiconductor substrate 11. Then, contact holes exposing the upper surfaces of the highly doped regions 18s and 18d are formed in the interlayer insulation film 21 using a known photolithographic process and a known etching process, and contact plugs 22s and 22d are formed by filling in tungsten (W) inside the contact holes. Then, by forming a conductive film on the interlayer insulation film 21 and processing this conductive film using a known photolithographic process and a known etching process, a source electrode 23s and a drain electrode 23d electrically connecting with the contact plugs 22s and 22d, respectively, are formed on the interlayer insulation film 21.

Taking the processes described above, the semiconductor device 2 having the structure represented by the cross section shown in FIG. 13 to FIG. 16 and FIG. 4 can be produced.

As described above, the semiconductor device 2 according to the second embodiment of the present invention has a semiconductor substrate 11, a gate insulator 13 formed on the semiconductor substrate 11, a gate electrode 15 which is formed on the gate insulator 13 and has a structure in which first bottom faces and second bottom faces, of which distance from the surface of the semiconductor substrate 11 is different from the first bottom faces, are disposed alternately along the gate width direction, and lightly doped regions 17s and 17d formed in regions except for a region underneath the gate electrode 15 in the semiconductor substrate 11.

In this way, by forming the gate electrode 15 as having parts that are close to the semiconductor substrate 11 (e.g. the first bottom faces) and parts that are far from the semiconductor substrate 11 (e.g. the second bottom faces), it is possible to form paths for the current flowing in between the source and drain, in boundary regions A, in addition to boundary regions a between the active region AR and the adjacent field regions FR under the gate electrode 15. Here, the boundary region A is a part where the close part with respect to the semiconductor substrate 11 switches to the far part with respect to the semiconductor substrate 11. Accordingly, in this structure, it is possible to increase the number of current paths as compared to the conventional cases. As a result, it is possible to realize a semiconductor device 2 having a good withstand voltage characteristic.

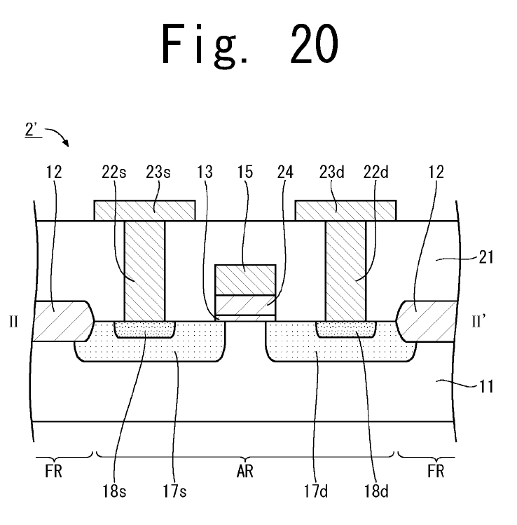

In addition, although the semiconductor device 2 according to the second embodiment of the present invention has a structure in which the insulation films 24 are formed under the gate insulator 13 and over the semiconductor substrate 11, the present invention is not limited to this structure. For instance, as shown in FIG. 20, a semiconductor device 2′ according to the present invention can have a structure in which the insulation films 24 are formed on the gate insulator 13.

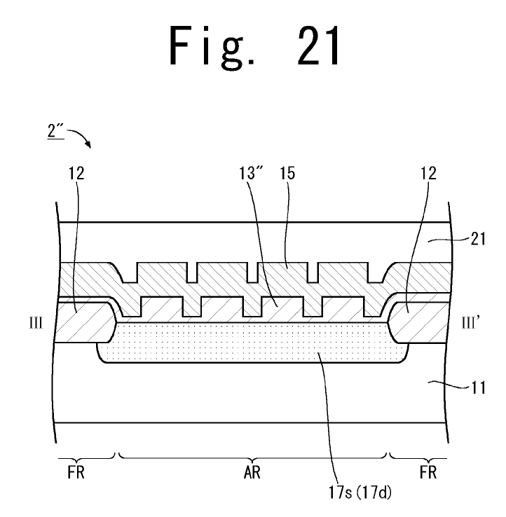

Furthermore, as shown in FIG. 21, a semiconductor device 2″ according to the present invention can have a structure in which a part of a gate insulator 13′ is made thicker instead of forming the insulation films 24.

As described above, any structure is applicable as long the gate electrode 15 is partially distanced from the semiconductor substrate 11. FIG. 20 is a view corresponding to FIG. 14 in the above description. FIG. 21 shows a structure corresponding to the structure shown in FIG. 15.

An electronic circuit comprising the semiconductor device 2 according to this embodiment has the same structure as the electronic circuit 100 described with reference to FIG. 12 in the first embodiment, and redundant explanations thereof will be omitted here.

While the preferred embodiments of the invention have been described using specific terms, such description is for illustrative purposes only, and it is to be understood that changes and variations may be made without departing from the spirit or the scope of the following claims.

This application claims priority to Japanese Patent Application No. 2005-95446. The entire disclosures of Japanese Patent Application No. 2005-95446 is hereby incorporated herein by reference.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

The term “configured” as used herein to describe a component, section or part of a device includes hardware and/or software that is constructed and/or programmed to carry out the desired function.

Moreover, terms that are expressed as “means-plus function” in the claims should include any structure that can be utilized to carry out the function of that part of the present invention.

The terms of degree such as “substantially,” “about,” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

What is claimed is:

1. A semiconductor device comprising:
a semiconductor substrate;
a gate insulator formed on the semiconductor substrate;
a gate electrode formed on the gate insulator, the gate electrode having first bottom faces, and second bottom faces in which the distance from the surface of the semiconductor substrate thereto is different from that of the first bottom faces, the first bottom faces and the second bottom faces being disposed alternately along a predetermined direction; and
a pair of lightly doped regions formed in regions of the semiconductor substrate except for a region underneath the gate electrode.

2. The semiconductor device according to claim 1, further comprising:
one or more insulation films formed on the semiconductor substrate, the one or more insulation films having first faces that are higher than the surface of the semiconductor substrate, wherein
the first bottom faces of the gate electrode lie above the insulation films.

3. The semiconductor device according to claim 2, further comprising:
one or more element isolating insulation films formed on the semiconductor substrate, wherein
the edges of the one or more insulation films have the same shapes as the edges of the one or more element isolating insulation films.

4. The semiconductor device according to claim 2, wherein
the semiconductor substrate is a silicon substrate, and
the one or more insulation films are silicon oxide films.

5. The semiconductor device according to claim 2, wherein the one or more insulation films are LOCOS films or a CVD films.

6. The semiconductor device according to claim 2, wherein the one or more insulation films are disposed at predetermined intervals.
